(19) United States
(12) Patent Application Publication
(10) Pub. No.: US 2017/0050345 A1
(43) Pub. Date: Feb. 23, 2017

(54) RESIN MOLDING METHOD AND RESIN MOLDING DIE SET

(71) Applicant: APIC YAMADA CORPORATION, Chikuma-shi, Nagano (JP)

(72) Inventors: Hideaki NAKAZAWA, Chikuma-shi, Nagano (JP); Masashi OKAMOTO, Chikuma-shi, Nagano (JP)

(73) Assignee: APIC YAMADA CORPORATION, Chikuma-shi, Nagano (JP)

(21) Appl. No.: 15/118,971

(22) PCT Filed: Feb. 27, 2015
(86) PCT No.: PCT/JP2015/055931

§ 371 Date: Aug. 15, 2016

(30) Foreign Application Priority Data
Mar. 17, 2014 (JP) 2014-052983

(51) Int. Cl. B29C 33/68; H01L 21/56; H05K 3/28; B29C 65/70

(52) U.S. Cl. CPC B29C 33/68; B29C 65/70; H01L 21/565; H05K 3/284; B29K 2101/10

(57) ABSTRACT

A technology capable of improving the production yield of molded articles. A film is supplied to a die surface of a resin molding die set. Next, the film is adhered to the die surface and caused to be in a state of being separated from the die surface at a corner section of a cavity recess. Next, a die set is closed to clamp the film. Next, a resin filling the interior of the cavity recess is thermoset, on the film provided therebetween, while adhering the film to the corner section.

### FIELD OF TECHNOLOGY

The present invention relates to an effective technology relating to a resin molding method and a resin molding die set.

### BACKGROUND TECHNOLOGY

Japanese Laid-open Patent Publication No. 2012-162013 (Patent Document 1) discloses a technology of sucking and holding a release film on an inner surface of a cavity recess so as to easily peel molded articles from the cavity recess formed in an upper resin molding die. The upper resin molding die has a clamper, which includes a through-hole (an accommodating hole), and a cavity piece (a cavity block) accommodated in the through-hole, and a clamper is relatively moved with respect to the cavity piece. Further, an inner bottom surface is constituted by a lower end surface of the cavity piece, and an inner wall surface is constituted by an inner wall surface of the through-hole.

In the technology disclosed in Patent Document 1, a die set is clamped in two steps (see a paragraph [0013] and drawings of FIGS. 12-16). Firstly, the release film, which has been supplied while opening a die set, is sucked and adhered onto the inner surface of the cavity recess, and the first clamping step is performed. Next, the cavity recess is filled with a resin, and the second clamping step is performed. By moving a clamper for performing the first to second clamping steps, a depth of the inner bottom surface of the cavity recess is reduced, so that a thickness of a molded article is set.

### PRIOR ART DOCUMENT

### Patent Document

### SUMMARY OF THE INVENTION

### Problems to be Solved by the Invention

However, the inventors newly found that problems will occur with increasing a difference (a standby step difference) between a position of the inner bottom surface of the cavity recess in the first clamping step (a standby position) and a position of the inner bottom surface of the cavity recess in the second clamping step (a mold position).

When the inner bottom surface is moved, from the deep standby position to the shallow mold position, by moving the clamper, the release film, which has been adhered to and held on the inner wall surface of the through-hole (the inner wall surface of the cavity recess), is slackened by the standby step difference. The slackened part of the release film projects in the interior of the cavity recess. If the resin molding is performed in such state, the release film will be bit by a molded part (a package) of the molded article, the release film cannot be easily peeled therefrom, wrinkles of the release film are copied on the surface of the molded article, etc., so production yield must be lowered.

An object of the present invention is to provide a technology capable of improving production yield of molded articles. This object, other objects and new characteristics of the present invention will be clarified by the present specification and attached drawings.

### Means for Solving the Problems

Typical inventions disclosed in the present application will be briefly explained as follows.

An example of a resin molding method of the present invention comprises the steps of: (a) supplying a film to a die surface of a resin molding die; (b) adhering the film to the die surface and causing the film to be in a state of being separated from the die surface at a corner section of a cavity recess after performing the step (a); (c) closing a die set to clamp the film after performing the step (b); and (d) thermosetting a resin filling the interior of the cavity recess, on the film provided therebetween, while adhering the film to the corner section. Preferably, in the step (b), the film is caused to be in the state of being separated from the die surface at the corner section after adhering the film to the die surface.

With the above described method, the film is adhered to the inner surface of the cavity recess without slacking the film in the cavity recess (without forming wrinkles of the film). Therefore, even if the resin filling the cavity recess is thermoset on the film provided therebetween, no film is bit by the molded part of the molded article, so that the film can be easily peeled and damaging an outer periphery of the molded part of the molded article, which is caused by peeling the film, can be prevented. Therefore, production yield of molded articles can be improved.

Preferably, the film is pulled by pressing the film with a projecting section, which is provided around an opening part of the cavity recess and which is projected from the die surface, so as to separate the film from the corner section. More preferably, the projecting section is constituted by a plurality of pins, and the pins are located to enclose the opening part of the cavity recess. Or, the projecting section is an annular frame enclosing the opening part of the cavity recess.

With the above described method, the film can be pulled, by the projecting section, from the interior of the cavity recess, and the film can be separated from the die surface at the corner section of the cavity recess.

More preferably, in the above example of the resin molding method, a depth of the cavity recess can be varied, and the film is adhered to and along the corner section, with reducing the depth of the cavity recess, in the step (d).

With the above described method, the film is separated from the die surface at the corner section in the cavity recess when the depth of the cavity recess is located at the standby position, and the film can be adhered to the inner surface of the cavity recess when the depth of the cavity recess is located at the mold position.

An example of a resin molding die set of the present invention comprises: one resin molding die having a cavity recess and the other resin molding die, which can be opened and closed and in which a resin filling the cavity recess is thermoset on a film, a clamper recess is formed around the cavity recess of the one resin molding die and recessed from a parting surface thereof, and a projecting section is projected from a parting surface of the other resin molding die and positioned to face the clamper recess, and the projecting section enters the clamper recess with pressing the film, by moving the one resin molding die and the other resin molding die close to each other, such that the film is pulled and separated from the corner section of the cavity recess. Preferably, the projecting section is constituted by a plurality of pins, and the pins are located to enclose the opening part of the cavity recess. Or, preferably, the projecting section is an annular frame enclosing the opening part of the cavity recess.

With the above described structure, the film is securely pulled from the interior of the cavity recess by the projecting section, and the film is adhered to the inner surface of the cavity recess without slacking the film in the cavity recess (without forming wrinkles of the film). Thus, the film is tightly adhered on the inner surface of the cavity recess. Therefore, even if the resin filling the cavity recess is thermoset on the film, no film is bit by the molded part of the molded article, so that the film can be easily peeled and damaging an outer periphery of the molded part of the molded article, which is caused by peeling the film, can be prevented. Therefore, production yield of molded articles can be improved.

Preferably, the resin molding die set further comprises: a supporting section for supporting the film, the supporting section being provided in the clamper recess; and an elastic member being provided in the clamper recess, the elastic member biasing the supporting section from an inner bottom surface of the clamper recess so as to support the supporting section.

With the above described structure, invasion of the film into the clamper recess, which is caused when the film is provided on the parting surface of the one resin molding die without providing the supporting section in the clamper recess, can be prevented.

Preferably, the resin molding die set further comprises: an insertion recess, into which the projecting section can be inserted, being recessed from the parting surface of the other resin molding die; and a shim for adjusting an amount of projecting the projecting section from the parting surface of the other resin molding die, the shim being provided in an inner bottom surface of the insertion recess.

With the above described structure, the projection amount of the projecting section can be easily adjusted, so that a desired amount of the film can be pulled.

Preferably, the resin molding die set further comprises: an accommodating recess, which is capable of accommodating a jig for supporting the film, being recessed from the parting surface of the one resin molding die and formed on an outer side of the clamper recess.

With the above described structure, even if the jig is used to easily hold and convey the film, the resin molding die set including the jig can be closed and can perform the resin molding.

### Effects of the Invention

The effect obtained by the typical examples of the present invention will be explained as follows.

By employing the resin molding technology of the present invention, the production yield of the molded articles can be improved.

### BRIEF DESCRIPTION OF THE DRAWINGS

FIG. 1 is a schematic sectional view of a resin molding die set of an embodiment of the present invention in operation.

FIG. 2 is a schematic sectional view of the resin molding die set which shows an action following the action of FIG. 1.

FIG. 3 is a schematic sectional view of the resin molding die set which shows an action following the action of FIG. 2.

FIG. 4 is a schematic sectional view of the resin molding die set which shows an action following the action of FIG. 3.

FIG. 5 is a schematic sectional view of the resin molding die set which shows an action following the action of FIG. 4.

FIG. 6 is a schematic sectional view of the resin molding die set which shows an action following the action of FIG. 5.

FIG. 7 is a schematic sectional view of the resin molding die set of another embodiment of the present invention in operation.

FIG. 8 is a schematic sectional view of the resin molding die set which shows an action following the action of FIG. 7.

FIG. 9 is a schematic sectional view of the resin molding die set of a further embodiment of the present invention in operation.

FIG. 10 is a schematic sectional view of the resin molding die set which shows an action following the action of FIG. 9.

FIG. 11 is a schematic sectional view of the resin molding die set which shows an action following the action of FIG. 10.

FIG. 12 is a schematic sectional view of the resin molding die set which shows an action following the action of FIG. 11.

### EMBODIMENTS OF THE INVENTION

In the following embodiments of the present invention, the description will be divided into a plurality of sections, but they are basically not independent of each other, one section relates to modified examples, details, etc. of a part or all of another section. Thus, a same symbol is applied to structural members having the same function, and explanation will not be repeated. Further, effects obtained by the same structure will not be repeated.

Numbers of structural members (including numbers of pieces, numeric values, quantities, ranges, etc.) are not limited to the described numbers except in case that the number is especially specified and that the number is theoretically clearly limited, so the numbers may be smaller or greater than the described ones. Further, as to shapes of structural members, the shapes include substantially similar shapes except in case that the shape is especially specified and that the shape is theoretically clearly excluded.

### First Embodiment

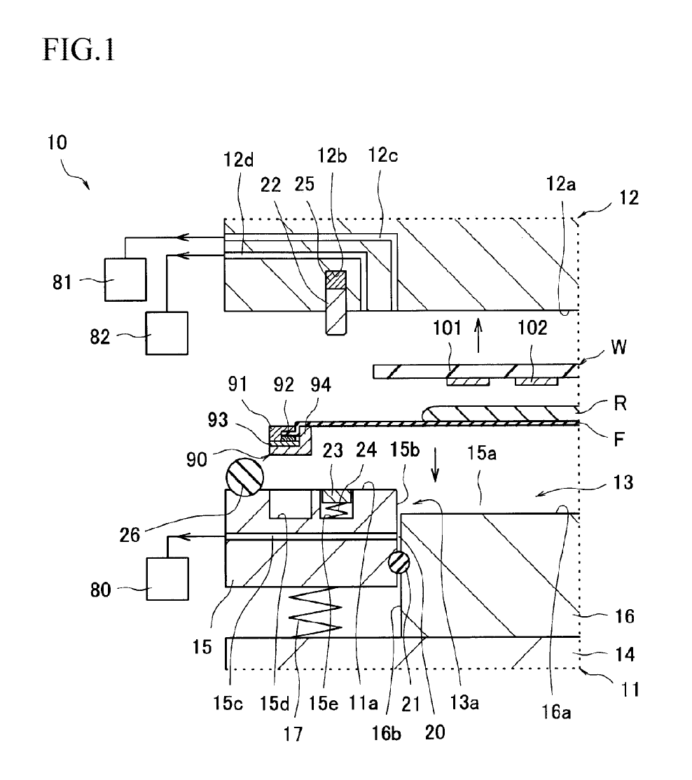

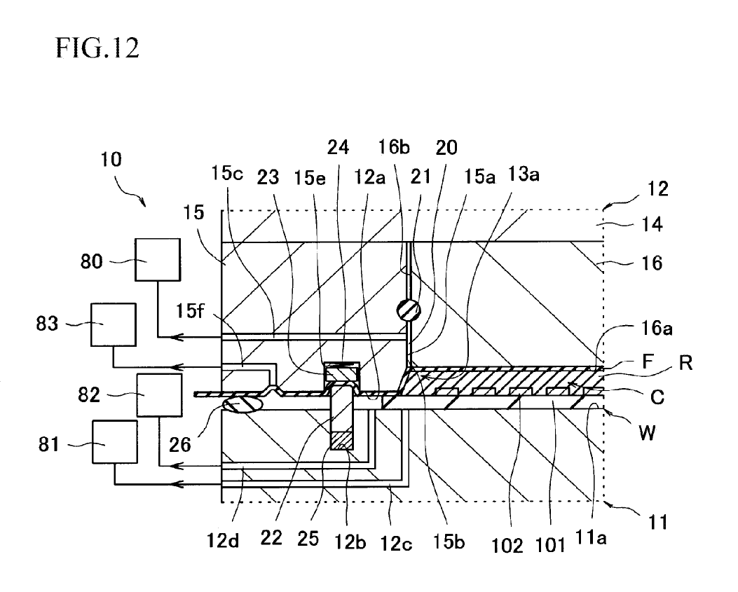

Firstly, a schematic structure of a resin molding die set 10 (a resin molding die mechanism) will be explained with reference to FIGS. 1-6. FIGS. 1-6 are schematic sectional views of the resin molding die set of the present embodiment, which show molding actions (actions for producing a molded article). In the present embodiment, a compression molding method is performed in the resin molding die set 10. In each of FIGS. 1-6 and FIGS. 7-12 showing other embodiments, an edge part of a cavity recess is shown as a main part of the resin molding die set 10. Note that, in each of the drawings, a center of the resin molding die set 10 is located on the right side of the shown part.

The resin molding die set 10 is constituted by a lower die 11, which corresponds to one resin molding die of claims, and an upper die 12, which is paired with the lower die 11 and which corresponds to the other resin molding die of the claims, and the dies can be opened and closed. The dies are opened and closed by a known press mechanism (not shown). Further, the resin molding die set 10 has a built-in heater, not shown, and can be heated until reaching a prescribed temperature (e.g., 180° C.).

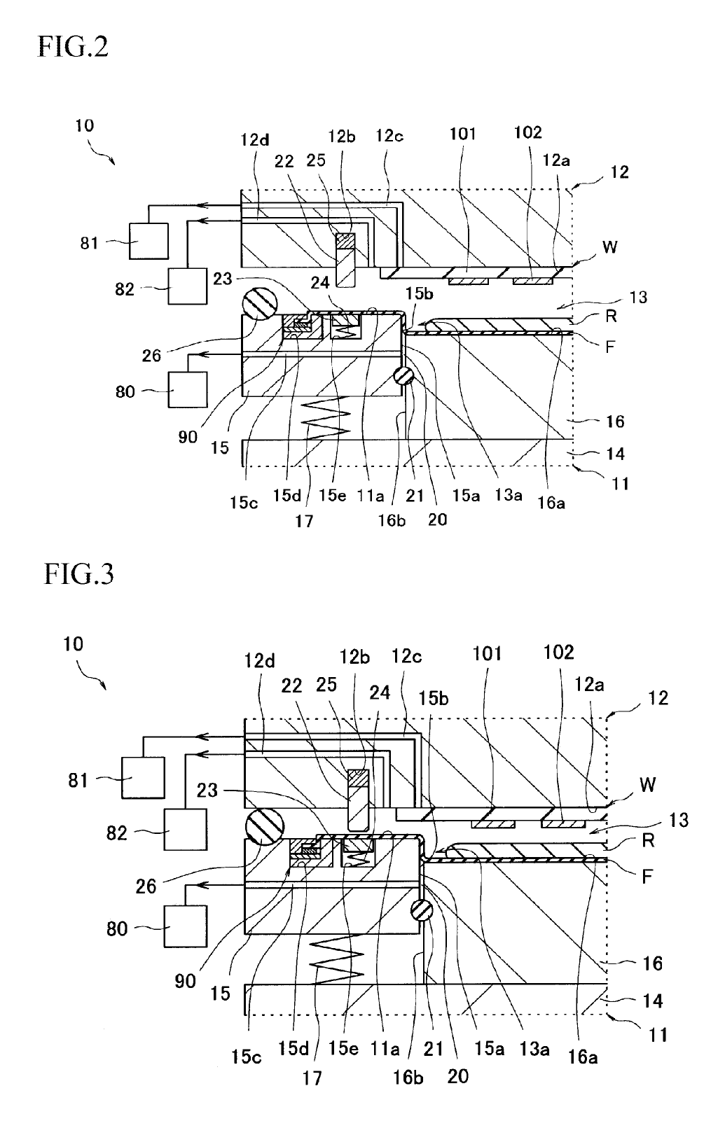

The lower die 11 has a parting surface 11a in which a cavity recess 13 having a circular or rectangular shape in a plan view is formed, and a release film F (hereinafter referred to as “film”) is supplied (set) onto the parting surface 11a including an inner surface of the cavity recess 13 while opening the resin molding die set 10 (see FIGS. 1 and 2). A resin R is supplied (set) into the cavity recess 13 with the film F. Further, a plate-shaped work W is supplied (set) onto a parting surface 12 of the upper die 12.

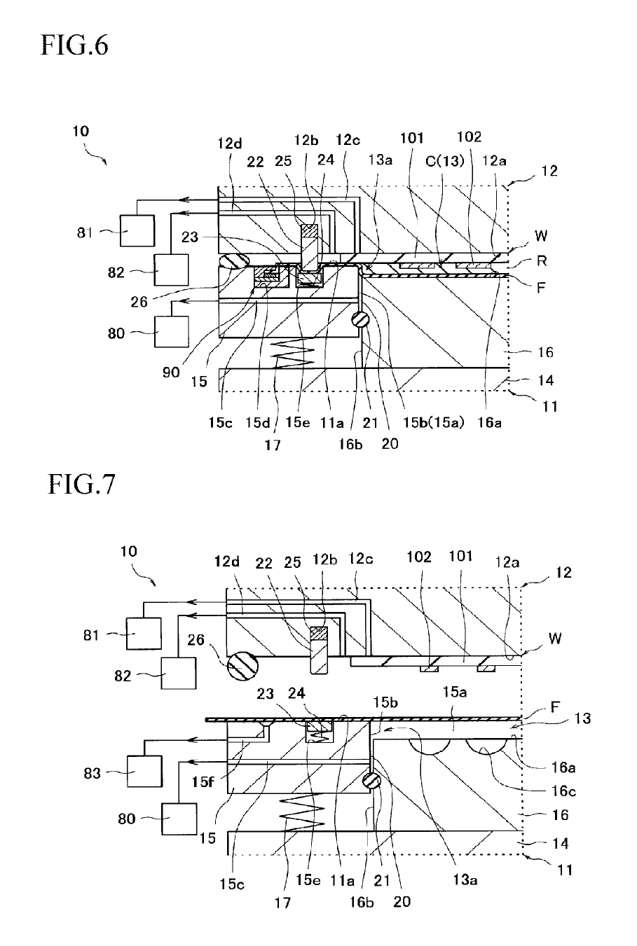

The work W is clamped by the lower die 11 and the upper die 12 by closing the resin molding die set 10 (see FIG. 5), and the cavity recess 13, whose opening part is closed by the work W, constitutes a cavity C. In a state where the resin molding die 10 is further closed (see FIG. 6), the resin R filling the cavity C (the cavity recess 13) is thermoset on the film F, so that the resin molding is performed.

Next, a concrete structure of the resin molding die set 10 will be explained. The lower die 11 and the upper die 12 are constituted by blocks mainly composed of alloy tool steel.

The lower die 11 has a base block 14, a clamper 15, a cavity piece 16 and elastic members 17, so that a depth (a height) of the cavity recess 13 can be varied. Concretely, the clamper 15 is assembled over the base block 14 with the elastic members 17 (e.g., springs). With this structure, the elastic members 17 are compressed by a clamping force of the resin molding die set 10 when the dies are closed, so that the clamper 15 is moved toward the base block 14. Note that, in case that a plurality of the cavities C are formed in one resin molding die set 10, the cavity pieces 16 may be assembled to the base block 14 with the elastic members 17 so as to equalize resin pressure.

The clamper 15 has a through-hole 15a, which is formed in an open-close direction of the dies. The cavity piece 16 is provided in the through-hole 15a and fixed to the base block 14. The clamper 15 is a block constituting an outer frame with respect to the cavity piece 16. As described above, the clamper 15 is moved with respect to the base block 14, and the cavity piece 16 is fixed, so that the cavity piece 16 is capable of moving, in the open-close direction of the dies, with respect to the clamper 15, in the lower die 11.

In the present embodiment, the cavity recess 13 is formed in the lower die 11, and an upper end surface 16a of the cavity piece 16, which is exposed in the through-hole 15a, constitutes an inner bottom surface of the cavity recess 13. Further, an inner wall surface 15b of the through-hole 15a constitutes an inner wall surface (an inner side surface) of the cavity recess 13. Since the cavity piece 16 relatively moves with respect to the clamper 15, a position of the upper end surface (flat surface) 16a of the cavity piece 16 can be moved from a standby position (see FIGS. 1-5), which is a deep position with respect to the parting surface 11a of the lower die 11 (an upper end surface of the clamper 15), to a mold position (see FIG. 6), which is a shallow position with respect thereto. Namely, the depth of the cavity recess 13 of the lower die 11 can be varied, so that the depth from the parting surface 11a to the inner bottom surface of the cavity recess 13 can be made deep and shallow.

Further, in the lower die 1, a sucking path 20 is formed between the inner wall surface 15b of the through-hole 15a of the clamper 15 and an outer circumferential surface 16b of the cavity piece 16. One end of the sucking path 20 is opened in a corner section 13a of the cavity recess 13 where the inner wall surface 15b of the through-hole 15a on the cavity recess side intersects with the upper end surface 16a of the cavity piece 16. The other end of the sucking path 20 is closed (sealed) by a sealing member 21 (e.g., O-ring) provided between the inner wall surface 15b and the outer circumferential surface 16b.

Further, in the lower die 11, a sucking path 15c, which communicates a part of the inner wall surface 15b above the sealing member 21 to the exterior of the die, is formed in the clamper 15, and the sucking path 15c is communicated to the sucking path 20. A decompression unit 80 (e.g., a vacuum pump) is provided to the exterior of the die, and the sucking path 15c is communicated (connected) to the decompression unit 80. By actuating the decompression unit 80, the film F set in the cavity recess 13 can be sucked through the sucking paths 15c and 20 and adhered.

By the way, in the present embodiment, the film F is formed into a strip shape so as to reduce an amount of film consumption, and the film is held and conveyed to the lower die 11 by a conveying jig 90 (see FIG. 1), which is constituted by circular plates 91, 92, 93 and 94. The plates of the conveying jig 90 pinch the film F and hold an outer periphery (entire periphery) of the film F, so that the film can be conveyed. Sectional shapes of the plates 91, 92, 93 and 94 are shown in FIG. 1, and planar shapes of the plates may be rectangular shapes or circular shapes. Note that, a rolled film, described later, may be employed as the film F.

A manner for holding the film F with the film conveying jig 90 will be explained. Firstly, the plate 92 is fitted into an inner step-shaped part of the plate 91, which is circularly formed and whose sectional shape is an L-shape, together with the film F so as to fix the film F between the plates 91 and 92. At this time, an outer periphery part and a center part of the film F (i.e., the entire film) are made flat. Note that, as described above, the entirely flat state of the film is omitted in the drawings.

Next, the plates 91 and 92, which pinch the film F, are mounted on an outer circumferential flange part (a lower part) of the plate 94, whose sectional shape is an L-shape, together with the plate 93. At this time, an inner part of the film F is stretched toward the outer periphery part, and the film is held by the film conveying jig 90 in a state where the center part is flat and the outer periphery part is bent. In this case, a stretching force applied to the film F can be easily adjusted by changing a thickness of the plate 93 or changing a thickness of a projecting section of the plate 94. In the present embodiment, the film conveying jig 90 conveys the film F together with the resin R, and the center part of the film F is flat during conveyance, so that the film conveying jig 90 is capable of stably conveying the resin R. Note that, only the film F may be supplied to the cavity recess 13 by the film conveying jig 90, and then the resin R may be separately supplied by using, for example, a conveying hand.

In the present embodiment, the clamper 15 has an accommodating recess 15d, which is formed around the through-hole 15a and recessed from the parting surface 11a (the upper end surface of the clamper 15), so as to accommodate the film conveying jig 90 in the die by the time of closing the dies. By fitting the film conveying jig 90 in the accommodating recess 15d, the film F can be set on the parting face ha in a state where the outer periphery of the film is stretched. The film F formed into a desired shape (e.g., strip-shaped film) can be used, and even if the film conveying jig 90 is used to easily hold and convey the film F, the resin molding can be performed without pinching the film conveying jig 90.

The clamper 15 further has a clamper recess 15e, which is formed on an inner side of the accommodating recess 15d (on the through-hole 15a side) and around the through-hole 15a and which is recessed from the parting surface 11a (the upper end surface of the clamper 15). As described later, a projecting section 22, which faces the clamper recess 15e and which is projected from a parting surface 12a of the upper die 12, can enter the clamper recess.

In the present embodiment, the clamper 15 further has a supporting section 23, which is provided in the clamper recess 15e so as to support the film F, and elastic members 24 (e.g., springs) for biasing and supporting the supporting section 23 with respect to an inner bottom surface of the clamper recess 15e. For example, elastic forces of the elastic members 24 are adjusted such that an upper end surface of the supporting section 23 exposed in the clamper recess 15e is made level with the parting surface 11a (the upper end surface of the clamper 15) in a state where the projecting section 22 does not enter the clamper recess (see FIG. 1). With this structure, pulling the film F into the clamper recess 15e, which is caused by, for example, sucking and adhering the film F to the cavity recess 13, can be prevented, and the film F of a desired width can be securely pulled out when the projecting section 22 enters the clamper recess. Note that, in case that no film F is pulled into the clamper recess 15e by suction, the supporting section 23 can be omitted.

As described above, the upper die 12 has the projecting section 22, which faces the clamper recess 15e and which is projected from the parting surface 12a, so as to pull out the film F from the cavity recess 13. By moving the lower die 11 and the upper die 12 close to each other, the projecting section 22 enters the clamper recess 15e with pressing the film F covering an opening part of the clamper recess 15e, so that it acts as a film pressing member.

Further, the upper die 12 has an insertion recess 12b, which is recessed from the parting surface 12a and in which the projecting section 22 is inserted, and a shim 25 (e.g., a plate-shaped block), which is provided to an inner bottom surface of the insertion recess 12b as a thickness adjusting member. By changing the thickness of the shim 25, a projection amount of the projecting section 22 from the parting surface 12a can be easily adjusted without exchanging the projecting section 22. Of course, the projection amount of the projecting section 22 may be adjusted by exchanging with the projecting section 22 having a different length without employing the shim 25. Further, the projection amount of the projecting section 22 may be adjusted by an actuating unit, e.g., a servo motor, as the thickness adjusting member. By adjusting the projection amount of the projecting section 22, a pulling amount of the film F can be set without excess or deficiency.

A structural example of the present embodiment, in which the clamper recesses 15, the supporting sections 23 and the elastic members 24 of the lower die 11 and the projecting sections 22 and the shims 25 of the upper die 12 are planarly arranged along the opening part of the cavity recess 13 and they enclose the same, will be explained. In this example, the projecting sections 22 may be blocks, whose planar shape is a rectangular shape, or pins, whose planar shape is a circular shape. The film F may be pulled out from the cavity recess 13 by a plurality of the projections 22, which are provided in the outer periphery of the cavity recess 13 and arranged at a regular interval.

Further, an annular frame, which covers the entire outer periphery (the opening part) of the cavity recess 13, may be employed as the projecting section 22. In this case, the clamper recess 15e may be a circular groove, which is formed along the through-hole 15 and into which the annular frame can be inserted. Note that, in case of employing the annular frame as the projecting section 22, the projecting section need not enclose the entire outer periphery of the cavity recess 13, and the projecting section may be partially cut.

The projection amounts of the projecting sections 22 may be respectively changed, by changing the projection sections 22 or changing the thickness adjusting members, at each position in the rectangular cavity recess 13, according to an amount of forming film wrinkles. For example, in case of the rectangular cavity recess 13, the projection amounts of corner sections are made different from those of side sections, so that the amount of pulling the film F by the projecting sections 22 (i.e., an amount of absorbing film wrinkles) can be adjusted. With this manner, even if amounts of forming wrinkles are partially different because, for example, distances from the center of the rectangular cavity recess 13 to the corner sections 13a (i.e., extension distances) are different, the film wrinkles can be suitably absorbed over the entire periphery of the cavity recess 13.

Further, in the upper die 12, the plate-shaped work W is sucked to the parting surface 12a. A sucking path 12c, which communicates a part of the parting surface 12a located on an inner side of the projecting sections 22 (a part facing the through-hole 15a) to the exterior of the die, is formed in the upper die 12. A decompression unit 81 (e.g., a vacuum pump) is provided to the exterior of the die, and the sucking path 12c is communicated (connected) to the decompression unit 81. By actuating the decompression unit 81, the work W set on the parting surface 12a can be sucked and held. Note that, the work W may be held by engaging claw sections provided in the parting surface 12a of the upper die 12, and this manner may be used in combination with the above described suction manner.

By the way, in the resin molding die set 10 of the present embodiment, a sealed space (a chamber) is formed in the resin molding die set 10 including the cavity recess 13, and then the sealed space is decompressed (see FIG. 3). A concrete structure will be explained.

In the resin molding die set 10, a sealing member 26 (e.g., O-ring) is provided along outer circumferential peripheries of the lower die 11 and the upper die 12 and pinched by the dies (concretely, the sealing member is provided in the outer circumferential periphery of the upper end surface of the clamper 15 (the parting surface 11a of the lower die 11)). The sealing member 26 is provided on an outer side of the accommodating recess 15d for accommodating the film conveying jig 90 (in an outer part of the die). By moving the lower die 11 and the upper die 12 close to each other, the dies press-contact the sealing member 26, so that an inner side of the sealing member 26, i.e., an inner space formed in the dies, including the cavity recess 13 is sealed and the sealed space is formed. Note that, the work W, the film F and the resin R are supplied into the resin molding die set before forming the sealed space.

A sucking path 12d, which communicates a part of the parting surface 12a located on an outer side of the sucking path 12c (the outer part of the die) to the exterior of the die, is formed in the upper die 12. A decompression unit 82 (e.g., a vacuum pump) is provided to the exterior of the die, and the sucking path 12d is communicated (connected) to the decompression unit 82. By actuating the decompression unit 82, the sealed space can be decompressed through the sucking path 12d. When the decompression is performed, the film F provided in the cavity recess 13 is sucked upward, but the film F is sucked through the sucking paths 15c and 20, so that the adhering state of the film F can be maintained.

In case of decompressing the inner space of the chamber and degassing air therefrom, the film F is sufficiently strongly sucked and adhered, against air suction for decompressing the inner space of the chamber, so as to maintain the adhering state of the film F, so the film F will be easily adhered to the corner section 13a. Note that, in the present embodiment, the sucking path 12d is opened in the part of the parting surface 12a, which is located on the inner side of the projecting sections 22 (located in the part facing the through-hole 15a); in case that, for example, the projecting sections 22 are pins which do not close air paths, the sucking path 12d may be formed on the outer side of the projecting sections 22 (in the outer part of the die) as far as the sucking path is formed on the inner side of the sealing member 26 (in the inner part of the die).

Next, actions of the resin molding die set 10 (a resin molding method) of the present embodiment will be explained. In the following description, the above described resin molding die set 10 is used, and molded articles (resin-molded products) are produced by the compression molding manner.

Firstly, as shown in FIGS. 1 and 2, in a state of opening the dies, the cavity piece 16 is relatively moved, with respect to the clamper 15, so as to previously locate the upper end surface 16a of the cavity piece 16 at the standby position. Further, the decompression units 80, 81 and 82 are previously actuated.

Further, the work W is conveyed into the resin molding die set by a loader (not shown) and set on (supplied to) the parting surface 12a. Further, the film F is conveyed into the resin molding die set by the film conveying jig 90. Further, as shown in FIG. 11, the resin R is mounted on the center part of the film F, so that the resin R may be conveyed into the resin molding die set together with the film F, or the resin R may be separately conveyed. Further, the resin R, which has been mounted on a plate-shaped member acting as a heat sink or a shielding plate, may be supplied onto the film F, or the resin R, the plate-shaped member and the film F may be supplied together. Further, the film F which has been preheated and softened may be supplied to the resin molding die set 10 so as to easily follow projections and recesses of the die, or the die surface may be heated by blowing hot air so as to make the film compulsorily follow a configuration of the cavity recess 13.

The plate-shaped work W includes, for example, a substrate 101 (e.g., a circuit board) and mounting parts 102 (e.g., semiconductor chips), and the plurality of mounting parts 102 are matrically mounted on the rectangular substrate 101. In the present embodiment, the substrate 101 is sucked and held on the parting surface 12a of the upper die 12 in a state where the mounting parts 102 face the lower die 11. The work W will be resin-molded to produce a molded article, in which a molded part (the resin R) enclosing the plurality of mounting parts 102 is formed on the substrate 101.

Further, the film F has heat resistance against heat of the resin molding die set 10 and is capable of easily peeled from the parting surface 11a of the lower die 11, so the film is composed of a film material having suitable softness and extensibility. The suitable film material of the film F is, for example, PTFE film, ETEF film, PET film, FEP film, fluorine-impregnated glass cloth, polypropylene film or polychlorinated vinylidene film.

Further, the resin R supplied onto the film F is, for example, liquid resin, powder resin or sheet resin. For example, the liquid resin may be supplied by a dispenser having a syringe capable of storing and injecting the liquid resin, or the powder resin may be supplied to a dispenser having a trough which is vibrated by an electromagnetic feeder so as to planarly supply the powder resin. Further, the sheet resin is supplied after peeling a protection sheet, which is used to prevent deterioration e.g., oxidization.

In case that such the resin R is conveyed together with the firm F, no resin R is supplied onto the film F in the resin molding die set, so that a preparation time of the resin molding die set 10 can be shortened, and scattering the powder resin R in the resin molding die set and heating the dispenser can be prevented. Since the resin molding die set 10 has been heated at a prescribed temperature by the built-in heater, the resin R is melted from a part contacting the inner bottom surface of the cavity recess 13.

Further, in the state of opening the resin molding die set 10 as shown in FIG. 2, the film F is tightly adhered to the die surface of the lower die 11 including the inner surface of the cavity recess 13 and the parting surface 11a. Concretely, the film F is set on the parting surface 11a of the lower die 11 so as to cover the inner surface of the cavity recess 13 and the opening part of the clamper recess 15e in the state where the upper end surface 16a of the cavity piece 16 is located at the standby position, and the film is sucked through the sucking path 20, so that the film F is adhered to the corner section 13a. In the parting surface 11a (the upper end surface of the clamper 16), the part of the film F covering the opening part of the clamper recess 15e is flatly supported by the supporting section 23.

Further, in the inner surface of the cavity recess 13, a part of the film F sucked through the sucking path 20 is sucked along the configuration of the cavity recess 13 because the decompression unit 80 is actuated. Therefore, the resin R mounted on the film F is set in the cavity recess 13 without changing its shape.

Further, in the parting surface 12a of the upper die 12, a rear surface of the substrate 101 (the opposite surface of the mounting surface on which the mounting parts 102 are mounted) is sucked and adhered through the sucking path 12c because the decompression unit 81 is actuated.

Successively, as shown in FIG. 3, the lower die 11 and the upper die 12 are moved close to each other until the sealing member 26 provided in the parting surface 11a of the lower die 11 contacts (sealing-touches) the parting surface 12a of the upper die 12. With this action, a sealed space is formed in the resin molding die set. Since the decompression unit 82 is actuated, the sealed space is decompressed through the sucking path 12d, so that an optional deaeration state can be produced in the tightly compressed space. In this case, the film F can be adhered to the corner section 13 as described above. In the resin molding method of the present embodiment including the compression molding process, decompression for preventing voids is usually required, so the film F is usually tightly adhered to the cavity recess 13 (including the corner section 13a) as a result.

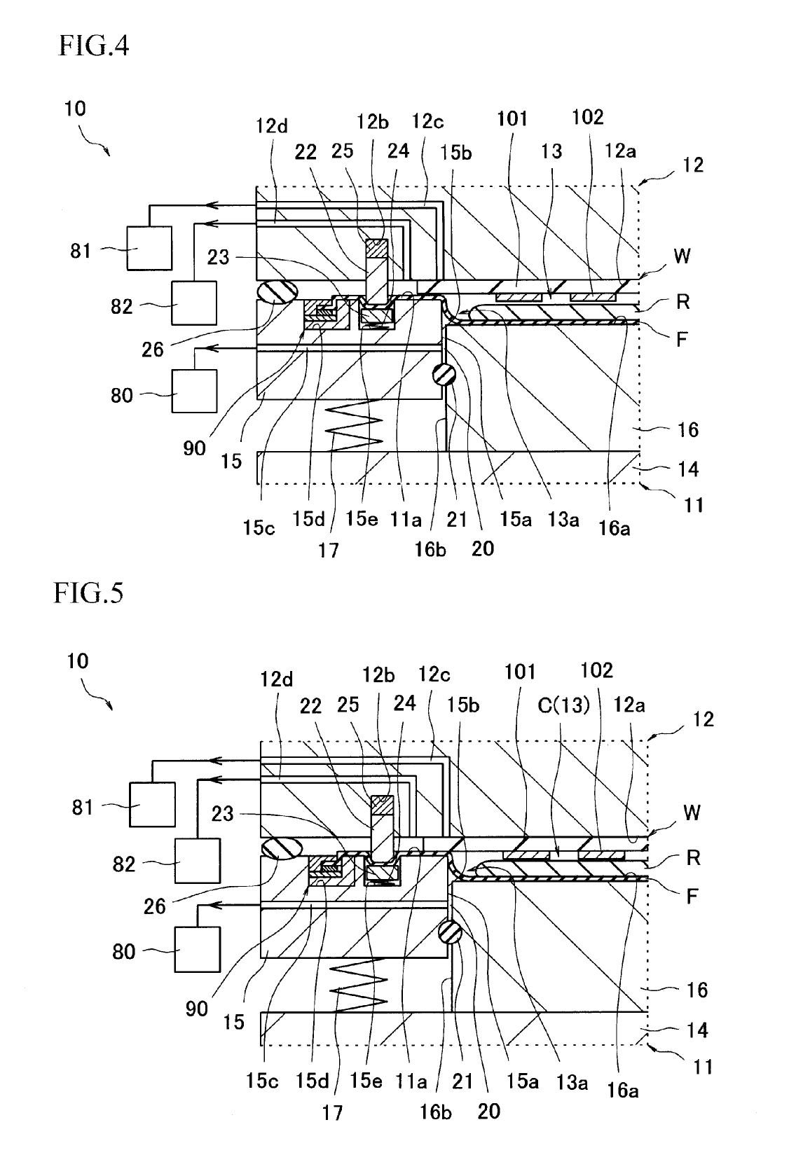

Successively, as shown in FIG. 4, the lower die 11 and the upper die 12 are further moved close to each other so as to make the projecting section 22 enter the clamper recess 15e with pressing the film F by the projecting section 22 and pull the film F from the cavity recess 13, then the film F is once separated from the corner section 13a. Namely, the film F is not adhered to the corner section 13a (is slackened), so the film F does not set along (follow) the configuration of the cavity recess 13. Even in the resin molding method in which the decompression process is required, the film F can be securely separated from the corner section 13a by compulsorily pulling the film F by the projecting section 22.

In the present stage, the film F is not clamped, in the peripheral of the opening part of the cavity recess 13, by the lower die 11 and the upper die 12 (the substrate 101). Namely, the resin molding die set 10 is not closed. If the film is clamped, the film F cannot be pulled out from the cavity recess 13, so the film F is not clamped by the lower die 11 and the upper die 12 in the present stage. As described above, the film F is pulled outward from the cavity recess 13, by the projecting section 22, from opening the resin molding die set until clamping the film F (the timing of pulling may be optional). In this case, the film F is pulled out, but a prescribed amount of the film is left so as to adhere the film to the cavity recess 13 at the mold position, so the film F is not adhered to the corner section 13 as a result.

Successively, as shown in FIG. 5, the lower die 11 and the upper die 12 are further moved close to each other so as to close the resin molding die set and clamp the film, in the periphery of the opening part of the cavity recess 13, by the lower die 11 and the upper die 12. Concretely, the film is clamped between the substrate 101 held by the upper die 12 and the clamper 15 of the lower die 11. Further, the opening part of the cavity recess 13 is closed by the work W (the substrate 101), so that the cavity C is formed. Note that, the decompression of the cavity recess 13 can be performed, after clamping the film F, by forming an air vent, not shown, in the clamper 15.

Successively, as shown in FIG. 6, the resin molding die set 10 further clamps so as to relatively move the cavity piece 16, with respect to the clamper 15, until the position of the upper end surface 16a of the cavity piece 16 from the parting surface 11a of the lower die 11 is moved from the deep standby position to the shallow mold position.

Concretely, the elastic members 17 are compressed by further clamping the resin molding die set 10, so that the clamper 15 is moved toward the base block 14 with being biased. The cavity piece 16 is relatively moved with respect to the clamper 15. At this time, the position of the upper end surface 16a of the cavity piece 16 is moved from the deep standby position to the shallow mold position. In this case, for example, if the film F is not pulled out before clamping the film and the film is adhered to the corner section 13a, the film F is remained at the corner section 13a with reducing the depth of the cavity C, so a part of the film F, which cannot be absorbed by elasticity of the film, is folded and bit by the resin R. On the other hand, in the present embodiment, the film F is previously pulled out to leave a prescribed amount of the film, which can be suitably adhered to the cavity recess 13 at the mold position without being slackened, and then the film is clamped, so that the film F can be suitably adhered along the corner section 31a while reducing the depth of the cavity recess 13. According to the above described view point, in case that the amount of moving the cavity recess 13 is necessarily great for resin-molding with the resin R whose volume will be easily increased when being supplied, e.g., granular resin, the effects of the present invention become superior.

Next, the resin R filling the cavity C is thermoset in a pressure-holding state with the film F being adhered to the corner section 13a. Next, the resin molding die set is opened to release the work W from the die, and then the work is further thermoset (post-cured) to complete the molded article. As described above, the film F is tightly adhered, without slackening the film F (without forming film wrinkles), in the cavity recess 13 including the corner section 13a, so that a problem of difficult peel-off of the film F, which is caused when the film is bit by an outer periphery of the molded part (the resin R) of the molded article (corresponding to the corner section 13a) and a problem of breaking the molded part (the resin R) of the molded article, which is caused when the film F is peeled, can be prevented even if the resin molding is performed by thermosetting the resin R filling the cavity recess 13 on the film F. Therefore, production yield of the molded articles can be improved.

### Second Embodiment

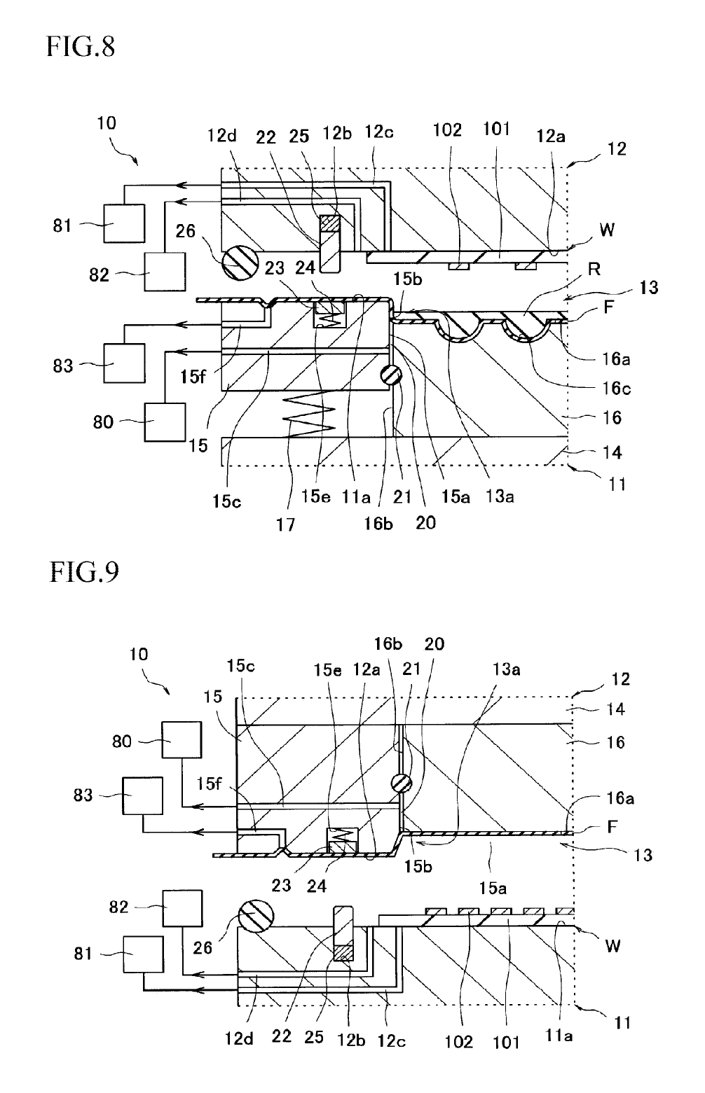

In the present embodiment, a case of resin-molding LED (Light Emitting Diode) lenses of LED chips will be explained with reference to FIGS. 7 and 8. FIGS. 7 and 8 are schematic sectional views of the resin molding die set 10 of the present embodiment of the present invention in operation (in a process of producing the molded article). In comparison with First Embodiment, the shape of the cavity piece 16 and the mechanism of conveying the film F are especially characterized in the resin molding die set 10 of the present embodiment, so the characterized points will be mainly explained. Note that, in the present embodiment, the molded article is LEDs (LED packages), so the work W includes a plurality of LED chips (mounting chips) which have been mounted on the substrate 101.

In the present embodiment, semispherical recesses 16c are recessed in the upper end surface 16a of the cavity piece 16 of the lower die 11. Thus, the LED lenses are molded by thermosetting the resin R filling the recesses 16c in a state where the LED chips 102 respectively face the recesses 16c. Note that, if the LED chips 102 can be protected, LED lenses other than convex lenses can be produced.

In case of the resin R for LED lens, reinforcing fillers included in the resin for molding ordinary semiconductor chips (resin-molded articles) are not included, so damaging molded articles (e.g., crack) is less occurred. However, soft silicone resin, whose bonding strength is lower than, for example, epoxy resin and which is in a rubber state under normal temperature, is usually used, so there is a possibility that the resin R will be peeled from the substrate 101 together with the film F if the film F bit by the resin-molded part (the resin R). It is effective to prevent the film from biting the resin R when reducing the depth of the cavity C as well as First Embodiment. For example, in case of molding the convex LED lenses, a thickness of the resin R around the LED chip is sometimes less than that of the LED chip 102, so the amount of varying the depth of the cavity C must be large and film wrinkles will be easily formed.

Further, in the present embodiment, the film F to be supplied to the parting surface 11a of the lower die 11 is rolled (rolled film). In case of using the rolled film F, a feeding roll and a collecting roll are provided in a direction perpendicular to a paper surface of each drawing, so the film F is supplied in the direction perpendicular to the paper surface of each drawing. The film F which has been supplied on the die surface is held by an outer periphery of the upper end surface of the clamper 15.

Thus, a sucking path 15f, which communicates a part of the upper end surface of the clamper 15 (the parting surface 11a) on the outer side of the clamper recess 15e (in the outer part of the die) to the exterior of the die, is formed. Further, a decompression unit 83 (e.g., a vacuum pump) is provided to the exterior of the die, and the sucking path 15f is communicated (connected) to the decompression unit 83. By actuating the decompression unit 83, the film F set on the parting surface 11a can be sucked and held. In this case too, the effect of the supporting section 23 for supporting the film F can be obtained. Further, in the present embodiment, the film F is held by the outer periphery of the upper end surface of the clamper 15, so the sealing member 26 is provided in the parting surface 12a of the upper die 12, not in the lower die 11.

Note that, in the present embodiment, the rolled film F is used, and it is held by the outer periphery of the upper end surface of the clamper 15, so the film conveying jig 90 for conveying the rectangular film F and the accommodating recess 15e for accommodating the jig, which have been explained in First Embodiment, are not required.

Next, a method of producing the LEDs as a molded article by using the resin molding die set 10 of the present embodiment will be explained.

Firstly, in the state of opening the dies shown in FIG. 7, the cavity piece 16 is relatively moved, with respect to the clamper 15, so as to previously locate the upper end surface 16a of the cavity piece 16 at the standby position. Further, the decompression units 80, 81, 82 and 83 are previously actuated.

The work W conveyed by the loader (not shown) is set on (supplied to) the parting surface 12a of the upper die 12 and sucked on the parting surface 12a through the sucking path 12c. As described above, the film F, which has been conveyed into the resin molding die set by the feeding roll and the collecting roll, is set on (supplied to) the parting surface 11a of the lower die 11 (see FIG. 7). Then, the film F is sucked through the sucking paths 15f and the 20, so that the film is tightly adhered on the die surface including the inner surface of the cavity recess 13 and the parting surface 11a (see FIG. 8).

Next, the resin R is supplied into the cavity recess 13, with the film F, by, for example, the syringe capable of storing and injecting the resin. Then, the above described steps shown in FIGS. 3-6 are performed so as to produce the LEDs. In the present embodiment too, the effects of First Embodiment can be obtained, and the production yield of the molded articles can be improved. Further, in case of molding the convex LED lenses, the film F must be tightly sucked to make the film F follow configurations of the recesses 16c. The film F can be tightly adhered on the die surface by blowing hot air to the film F from upward and pressing the film F onto surfaces of the recesses 16c, so that forming film wrinkles can be prevented.

### Third Embodiment

In the above described First and Second Embodiments, the manners of varying the depth of the cavity recess 13 during the compression molding have been explained. In the present embodiment, a transfer molding method, in which the depth of the cavity recess 13 is fixed, will be explained with reference to FIGS. 9-12. FIGS. 9-12 are schematic sectional views of the resin molding die set 10 of the present embodiment of the present invention in operation (in a process of producing the molded article). Note that, in the resin molding die set 10 for performing the transfer molding method, a known transfer mechanism pressure-feeds the resin to the cavity C, by a plunger (not shown) which is provided in a pot (not shown) and capable of reciprocally moving therein, via a resin path communicated to the cavity C.

In the resin molding die set 10 of the present embodiment, the cavity recess 13 is formed in the upper die 12, so the structural members of the resin molding die set, which have been explained in First and Second Embodiments, are basically invertedly arranged. Further, in the present embodiment, the film F to be supplied onto the parting surface 12a of the upper die 12 is the rolled film, so the structural members of the film conveying mechanism, which have been explained in Second Embodiment, are invertedly arranged. Further, the clamper 15 is provided with no elastic members 17, so the depth of the cavity recess 13 is fixed.

Next, the transfer resin molding method performed in the resin molding die set 10 will be explained.

Firstly, in the state of opening the dies shown in FIG. 9, the film F is supplied to the inner surface of the cavity recess 14 and the parting surface 12a of the upper die 12, and the film F is adhered to the die surface. The work W is set (supplied) onto the parting surface 11a of the lower die 11, and the resin R is supplied to the pot.

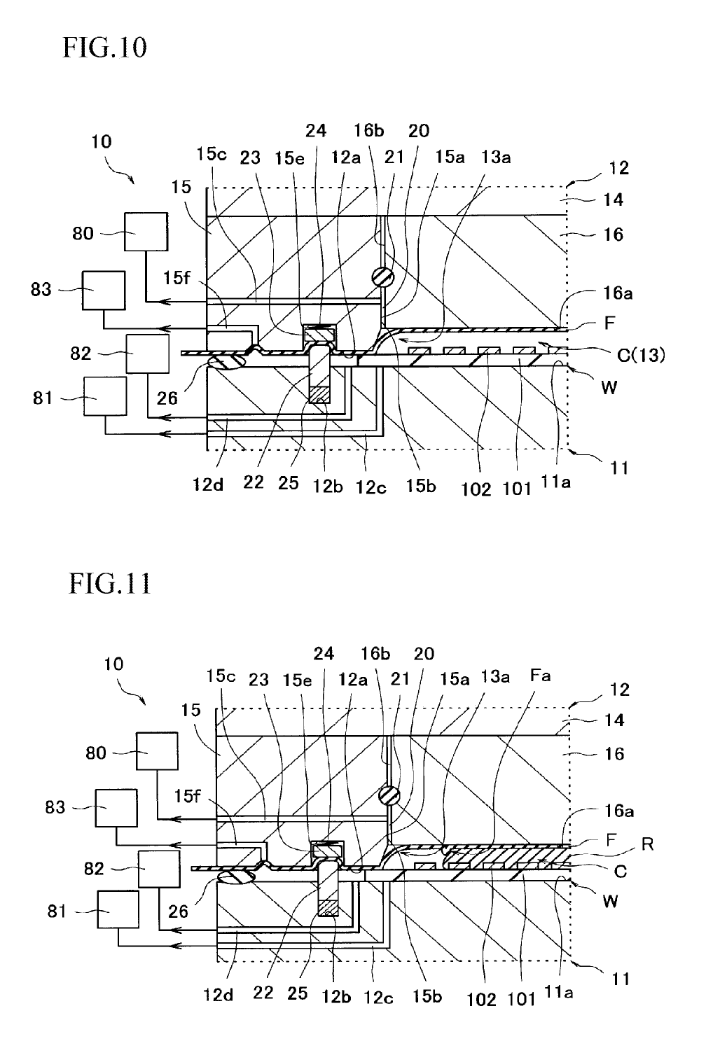

Next, the lower die 11 and the upper die 12 are moved close to each other so as to make the projecting section 22 enter the clamper recess 15e with pressing the film F by the projecting section 22 and pull the film F from the cavity recess 13, then the film F is once separated from the die surface at the corner section 13a. Successively, as shown in FIG. 10, the lower die 11 and the upper die 12 are further moved close to each other so as to close the resin molding die set and clamp the film, in the periphery of the opening part of the cavity recess 13, by the lower die 11 and the upper die 12. Concretely, the film is clamped between the substrate 101 held by the lower die 11 and the clamper 15 of the upper die 12.

Successively, as shown in FIG. 11, the resin R is supplied into the cavity C by actuating the transfer mechanism. By this action, the resin R flows from one side edge of the cavity C to the other side edge (from a right side to a left side in FIG. 11 in the drawing), but the film F is pushed by a front end (a flow front) of the flow of the resin R, so film a wrinkle Fa will be formed on the midway of the flow.

However, when the cavity C is fully filled with the resin R by further actuating the transfer mechanism, a slackened part, i.e., the film wrinkle Fa, is absorbed by the corner section 13a, so that the film F is adhered. Even in the cavity recess 13 whose depth is fixed, the film wrinkle Fa is absorbed by the corner section 13a, so that breaking the molded article can be prevented. Then, the resin R filling the cavity C is thermoset, in a pressure-holding state, with adhering the film F to the corner section 13a. Next, the resin molding die set is opened to release the work W from the die, and then the work is further thermoset (post-cured) to complete the molded article. In the present embodiment too, the effects of First and Second Embodiments can be obtained, and the production yield of the molded articles can be improved.

The embodiments of the present invention have been concretely explained above, but the present invention is not limited to the above described embodiments, so the present invention may be varied without deviating the scope thereof.

For example, in the above described First to Third Embodiments, the projecting section 22 is provided, and the film F is separated from the corner section 13a by pushing the film with the projecting section 22 so as to pull the film F toward the outside of the cavity recess 13. Further, the projecting section 22 may be omitted, and the film F may be separated from the corner section 13a by adjusting a setting condition of the film F with the decompression unit 80, which is communicated to the sucking path 20 opened at the corner section 13a, or the film conveying mechanism. Further, a sucking path may be formed in the clamper recess 15e, a decompression unit communicating thereto may be provided, and the clamper recess 15e may suck the film F so as to pull the film toward the outside of the cavity recess 13. Further, a film handler, which is capable of supporting (holding) a part of the film F located outside of the die and pulling the film sideward, may be separately provided so as to pull the film at a prescribed timing of the former embodiments.

In the above described First Embodiment, the strip-shaped film F is used. But, the rolled film may be used as the film F in said embodiment. In case of using the rolled film F, the film is extended from a feeding roll, passed through the inside of the opened resin molding die set and collected by a collecting roll. In this time, the film F is stretched between the feeding roll and the collecting roll, so the clamper recess 15e of the lower die 11 and the projecting section 22 of the upper die 12 need not be planarly arranged to entirely enclose the opening part of the cavity recess 13 and the work W. For example, the clamper recess 15e and the projection 22 may be located at a position corresponding to a part of the film where stretching tension of the film is low. Further, in case that the projection amount of the projecting section 22 is adjustable and that extending the film F is not required, the resin molding die set can be used as an ordinary resin molding die by prohibiting the projecting section 22 to enter the clamper recess 15e.

Further, in the above described First and Second Embodiments, the resin molding die set for performing the transfer molding method is used. In said embodiments, the TCM (Transfer Compression Mold) die set described in Patent Document 1 and other transfer molding die sets may be used as the resin molding die set.

Further, in the above described Third Embodiment, the transfer resin molding method is performed in the resin molding die set in which the depth of the cavity recess 13 is fixed. The present invention can be applied to the compression resin molding method in which the depth of the cavity recess 13 is fixed and in which the resin R supplied to the center part of the cavity recess 13 is spread outward.

Further, as a further embodiment, the film F may be adhered onto the die surface (except the corner section 13a), and the film F may be separated from the die surface at the corner section 13a. In this case, a sucking force of the decompression unit 80, which is communicated to the sucking path 20, is set lower than the case of adhering the film to the corner section 13a, so that the film F can be adhered onto the die surface except the corner section 13a. On the other hand, in the above described First to Third Embodiments, the film F is adhered onto the die surface (including the corner section 13a), and then the film F is separated from the die surface at the corner section 13a.

1. A resin molding method,
comprising the steps of:
(a) supplying a film to a die surface of a resin molding die;
(b) adhering the film to the die surface and causing the film to be in a state of being separated from the die surface at a corner section of a cavity recess after performing the step (a);
(c) closing a die set to clamp the film after performing the step (b); and
(d) thermosetting a resin filling the interior of the cavity recess on the film provided therebetween, while adhering the film to the corner section.

2. The resin molding method according to claim 1,
wherein, in the step (b), the film is caused to be in the state of being separated from the die surface at the corner section after adhering the film to the die surface.

3. The resin molding method according to claim 1,
wherein, in the step (b), the film is pulled by pressing the film with a projecting section, which is provided around an opening part of the cavity recess and which is projected from the die surface, so as to separate the film from the corner section.

4. The resin molding method according to claim 3,
wherein the projecting section is constituted by a plurality of pins, and
the pins are located to enclose the opening part of the cavity recess.

5. The resin molding method according to claim 3,
wherein the projecting section is an annular frame enclosing the opening part of the cavity recess.

6. The resin molding method according to claim 1,
wherein a depth of the cavity recess can be varied, and
the film is adhered to and along the corner section, with reducing the depth of the cavity recess, in the step (d).

7. A resin molding die set, comprising:
one resin molding die having a cavity recess and the other resin molding die, which can be opened and closed and in which a resin filling the cavity recess is thermoset on a film,
wherein a clamper recess is formed around the cavity recess of the one resin molding die and recessed from a parting surface thereof, and a projecting section is projected from a parting surface of the other resin molding die and positioned to face the clamper recess, and
wherein the projecting section enters the clamper recess with pressing the film, by moving the one resin molding die and the other resin molding die close to each other, such that the film is pulled and separated from the corner section of the cavity recess.

8. The resin molding die set according to claim 7,
wherein the projecting section is constituted by a plurality of pins, and
the pins are located to enclose the opening part of the cavity recess.

9. The resin molding die set according to claim 7,
wherein the projecting section is an annular frame enclosing the opening part of the cavity recess.

10. The resin molding die set according to claim 7, further comprising:
a supporting section for supporting the film, the supporting section being provided in the clamper recess; and
an elastic member being provided in the clamper recess, the elastic member biasing the supporting section from an inner bottom surface of the clamper recess so as to support the supporting section.

11. The resin molding die set according to claim 7, further comprising:
an insertion recess, into which the projecting section can be inserted, being recessed from the parting surface of the other resin molding die; and
a shim for adjusting an amount of projecting the projecting section from the parting surface of the other resin molding die, the shim being provided in an inner bottom surface of the insertion recess.

12. The resin molding die set according to claim 7, further comprising:
an accommodating recess, which is capable of accommodating a jig for supporting the film, being recessed from the parting surface of the one resin molding die and formed on an outer side of the clamper recess.
